(19) United States
(12) Patent Application Publication
(10) Pub. No.: US 2016/0365853 A1
(43) Pub. Date: Dec. 15, 2016

(54) ELECTROMECHANICAL SWITCH VIA WIRING CONNECTOR

(71) Applicant: Magna Closures Inc., Newmarket (CA)

(72) Inventors: John G. Zeabari, Highland, MI (US); Thomas McGettrick, Plymouth, MI (US); Joshua M. Bernhardt, West Bloomfield, MI (US)

(21) Appl. No.: 15/162,792

(22) Filed: May 24, 2016

Related U.S. Application Data
(60) Provisional application No. 62/172,832, filed on Jun. 9, 2015.

(51) Int. Cl. H03K 17/687; H01R 13/66; H01L 27/02; H01L 27/06; H01L 29/78; H01L 29/866

(52) U.S. Cl. CPC H03K 17/687; H01L 29/7805; H01L 29/866; H01L 27/0255; H01L 27/0629; H01R 13/665

(57) ABSTRACT

A switching system is disclosed and includes a first device including a dormant local supply and a ground source and a first device connector having a plurality of first device terminals. The first device includes a switching unit for selectively coupling a first device power terminal to the dormant local supply in an on mode and for decoupling the first device power terminal and the dormant local supply in an off mode. A cable subassembly includes a shield and a first cable connector including a plurality of first cable connector terminals for connection to the first device terminals. The shield is connected to a first cable ground terminal for interconnecting the first device power terminal to the dormant local supply in response to the first cable connector engaging the first device connector and forming a conductive path through the shield to the ground source and activating the switching unit.

### CROSS-REFERENCE TO RELATED APPLICATIONS

This application claims the benefit of U.S. Provisional Application No. 62/172,832 filed Jun. 9, 2015. The entire disclosure of the above application is incorporated herein by reference.

### FIELD

The present disclosure relates generally to an electromechanical switch, more particularly, to an electromechanical switch system using a wiring connector.

### BACKGROUND

This section provides background information related to the present disclosure which is not necessarily prior art.

Electronic control units (ECU) executing software or electronic instructions are commonly found on vehicles for a myriad of uses. During the engineering development process, the vehicle manufacturers and the suppliers providing each ECU may find it necessary to reprogram the software that is executed on the ECU (i.e., “re-flash” the software on the ECU). Many ECUs may include reprogramming interfaces and corresponding wiring connectors, such as those meeting the standards for Universal Serial Bus (USB) to allow the ECU to be reprogrammed with updated software using a personal computer or specialized reprogramming tool. However, when the ECU is not being reprogrammed, there may be no need to provide power to portions of the ECU, such as the USB circuitry. Therefore, this circuitry may be isolated or switched off at times. However, known switching systems generally include costly integrated circuits and/or take up a large amount of space. Accordingly, there exists a need for an improved switching system.

### SUMMARY

This section provides a general summary of the present disclosure and is not intended to be interpreted as a comprehensive disclosure of its full scope or all of its features, aspects and objectives.

Accordingly, it is an aspect of the present disclosure to provide a device including an active supply node for coupling to an active electrical supply from a second device. The device also includes a dormant local supply node for selectively supplying power to said device and a first device connector for coupling with the second device through a cable subassembly. A switching unit is coupled to the dormant local supply node and the active supply node and to the first device connector and is configured to selectively decouple the active supply node and the dormant local supply node in an off mode in response to the cable subassembly disengaging the first device connector. The switching unit is also configured to couple the active supply node to the dormant local supply node in an on mode in response to the cable subassembly engaging the first device connector.

According to another aspect of the disclosure a device is provided that includes an active supply node for coupling to an active electrical supply from a second device. The device also includes a dormant local supply node for selectively supplying power to the device and a first device connector having a plurality of first device terminals for coupling with the second device through a cable subassembly. The cable subassembly includes a first cable connector including a plurality of first cable connector terminals for connection to the first device terminals and a shield electrically connected to the first cable connector and at least one of the first cable connector terminals. The device further includes a shield node for coupling with the shield of the cable subassembly through the first device connector. A switching unit is coupled to the dormant local supply node and the active supply node and to the shield node. The switching unit is operable for selectively decoupling the active supply node and the dormant local supply node in an off mode in response to the first cable connector of the cable subassembly disengaging the first device connector. The switching unit additionally couples the active supply node to the dormant local supply node in an on mode in response to the first cable connector of the cable subassembly engaging the first device connector and forming a conductive path through the shield and the at least one of said first device terminals to activate the switching unit.

According to yet another aspect of the disclosure, a switching system is also provided. The switching system includes a first device including a dormant local supply for selectively powering the first device and a first device connector having a plurality of first device terminals. The first device includes a switching unit for selectively coupling at least one of the plurality of first device terminals to the dormant local supply in an on mode. The switching unit also decouples at least one of the first device terminals and the dormant local supply in an off mode. The switching system also includes a cable subassembly including a shield and a first cable connector having a plurality of first cable connector terminals for connection to the first device terminals. A second device is coupled to the cable subassembly for selectively providing power to the first device through at least one of the plurality of first device terminals. The shield of the cable subassembly is electrically connected to at least one of the first cable connector terminals for electrically interconnecting at least one of the first device terminals to the dormant local supply in response to the first cable connector of the cable subassembly engaging the first device connector and forming a conductive path through the shield and at least one of the first device terminals and activating the switching unit.

These and other aspects and areas of applicability will become apparent from the description provided herein. The description and specific examples in this summary are intended for purpose of illustration only and are not intended to limit the scope of the present disclosure.

### DRAWINGS

The drawings described herein are for illustrative purposes only of selected embodiments and not all implementations, and are not intended to limit the present disclosure to only that actually shown. With this in mind, various features and advantages of example embodiments of the present disclosure will become apparent from the following written description when considered in combination with the appended drawings, in which:

FIG. 1 is a diagram illustrating a cable subassembly and a first device with a first device connector of a switching system according to an aspect of the disclosure;

FIG. 2 is a top view of a first device illustrating a printed circuit board and the first device connector of the switching system according to an aspect of the disclosure;

FIG. 3 is an enlarged partial view of the printed circuit board of the first device shown in FIG. 2;

FIG. 4 is a perspective view of the first device connector illustrating the first device terminals of the switching system according to an aspect of the disclosure;

FIG. 5 is a perspective view of a first cable connector in the first device connector of FIG. 4;

FIG. 6 is a diagram illustrating the first device connector of the first device of the switching system according to an aspect of the disclosure;

FIG. 7 is a diagram illustrating a switching unit of the first device of the switching system according to an aspect of the disclosure; and

FIG. 8 is a perspective view of the first device connector and the first cable connector according to an aspect of the disclosure.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to switching systems of the type well-suited for use in virtually any application. The switching system of this disclosure will be described in conjunction with one or more example embodiments. However, the specific example embodiments disclosed are merely provided to describe the inventive concepts, features, advantages and objectives will sufficient clarity to permit those skilled in this art to understand and practice the disclosure.

More specifically, the present disclosure relates to a switching system for isolating or selectively connecting a dormant electrical supply to an active electrical supply (i.e., a secondary power supply). For example, the switching system may be used isolate a portion of the circuitry of an electronic control unit (ECU) on a vehicle, such as a universal serial bus (USB) circuit when a cable is not plugged in and connects the isolated circuitry to an active voltage supply (e.g., active USB voltage, typically 5 volts) from a computer when the cable is plugged into the ECU. Therefore, the unused portion of the ECU circuitry (e.g., USB circuit) may be isolated when the cable is not connected and when vehicle power is applied. The switching system may also may be used to provide a dual power source for a micro controller or entire ECU (i.e. using vehicle power or power from a secondary power supply such as the active USB voltage) when programming the controller or ECU, for instance.

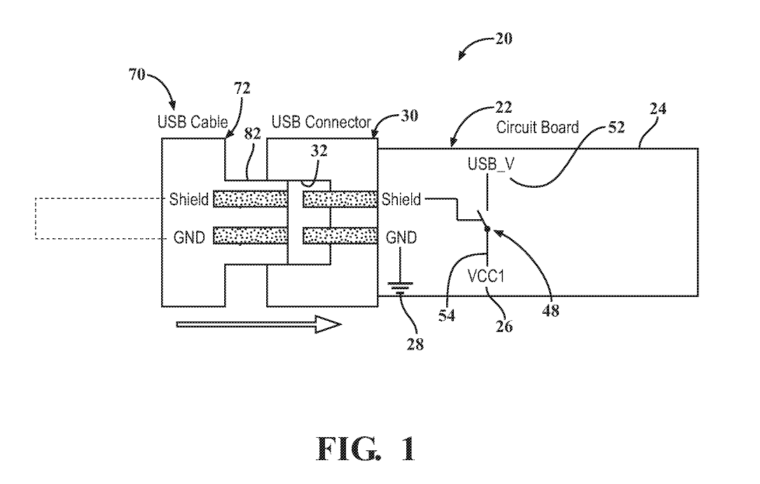

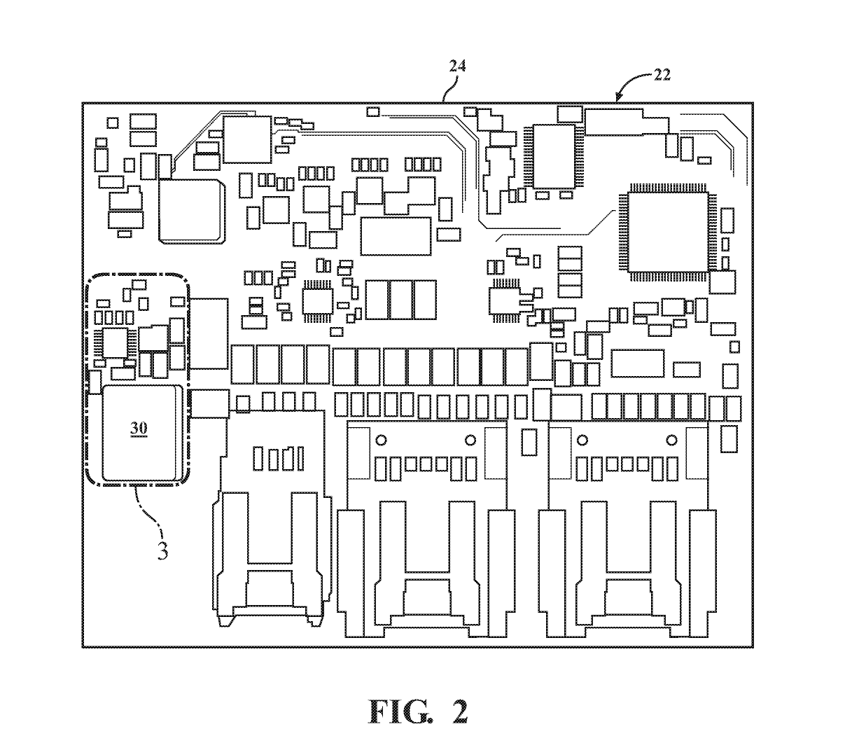

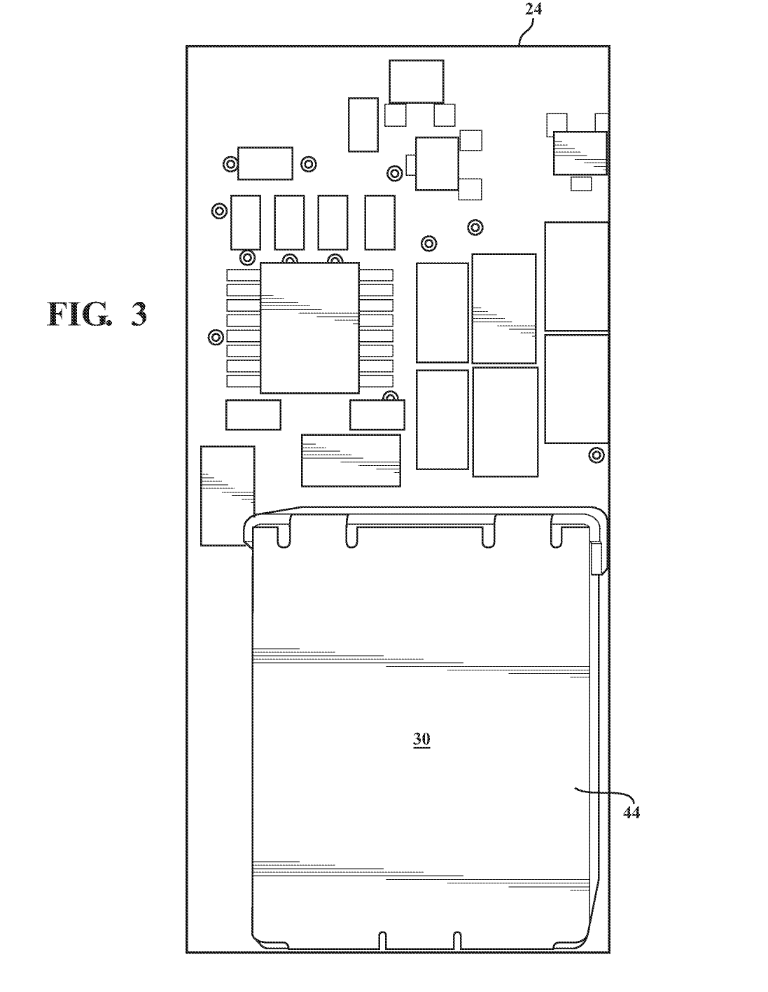

Referring to the Figures, wherein like numerals indicate corresponding parts throughout the several views, a switching system 20 is disclosed. As best shown in FIGS. 1-3, the switching system 20 includes a first device 22 including a printed circuit board 24 (FIG. 2) having a dormant local supply 26 and a ground source 28 and including a first device connector 30 (FIG. 3) attached to and electrically connected to the printed circuit board 24 and defining a cavity 32. According to an aspect of the disclosure, the dormant local supply 26 can connect to and supply power to components of the first device 22, such as, but not limited to a micro controller (not shown).

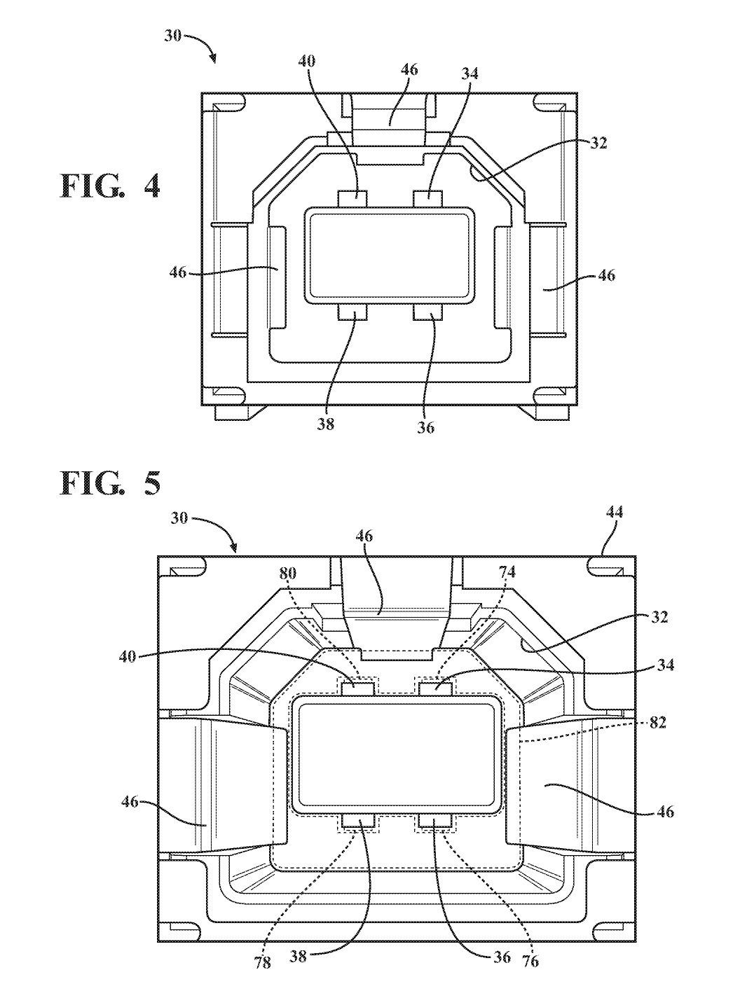

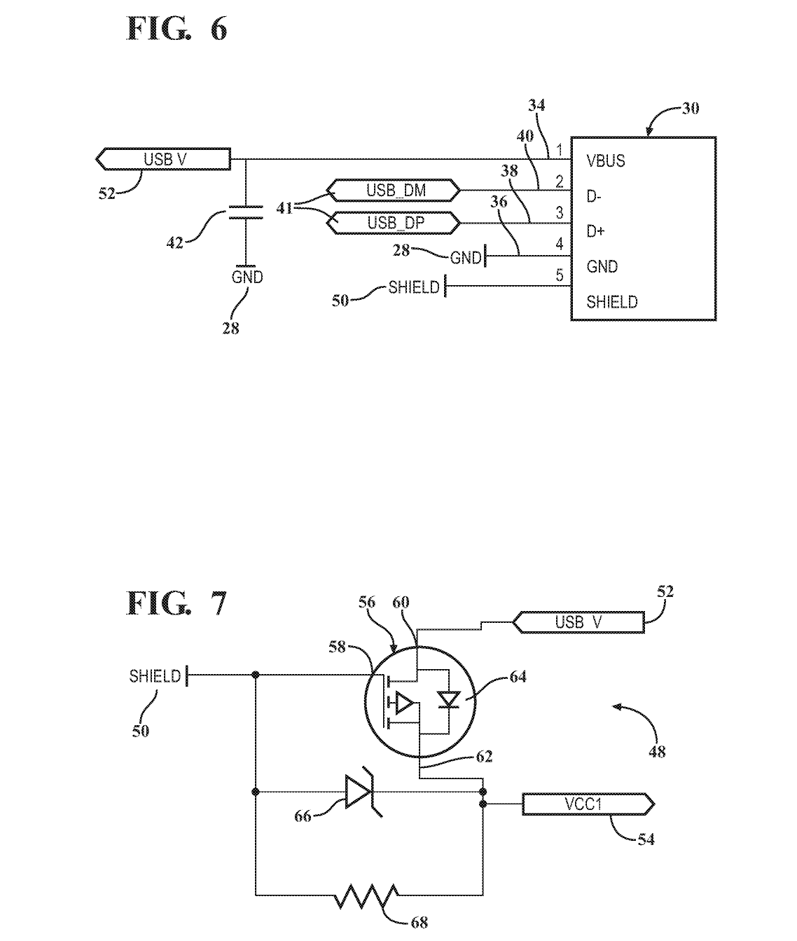

As best shown in FIGS. 4-6, the first device connector 30 includes a plurality of first device terminals 34, 36, 38, 40 disposed in the cavity 32. The first device terminals 34, 36, 38, 40 include a first device power terminal 34 and a first device ground terminal 36 that is electrically interconnected with the ground source 28 and a first device positive data terminal 38 and a first device negative data terminal 40. The data terminals 38, 40 connect to corresponding data nodes 41 (FIG. 6) that may connect to a transceiver or bus controller (not shown), for example. The first device 22 also includes a capacitor 42 (FIG. 6) electrically connected between the first device power terminal 34 and the ground source 28 for filtering electrical noise. The first device connector 30 includes a housing 44 (FIGS. 3 and 5) electrically connected to the printed circuit board 24 and disposed about and in a spaced relationship from the first device terminals 34, 36, 38, 40 for shielding the first device terminals 34, 36, 38, 40 from electromagnetic interference and for preventing the first device terminals 34, 36, 38, 40 from emitting electromagnetic interference. The housing 44 of the first device connector 30 includes a plurality of tabs 46 extending into the cavity 32. According to an aspect of the disclosure, the first device connector 30 is a female standard USB B-type connector; however, it should be appreciated that the first device connector 30 could be another type of connector, such as, but not limited to other USB types (e.g., A-type USB, mini USB, micro USB, etc.), Apple® Lightning connector, eSATA, or Firewire.

Referring now to FIG. 7, the first device 22 includes a switching unit 48 attached to and electrically connected to the printed circuit board 24 and including a shield node 50 electrically connected to the housing 44 and an active supply node 52 electrically connected to the first device power terminal 34 and a dormant supply node 54 electrically connected to the dormant local supply 26. According to an aspect of the disclosure, the switching unit 48 includes a metal-oxide-semiconductor field-effect transistor (MOSFET 56) having a gate 58 electrically connected to the shield node 50 and a drain 60 electrically connected to the active supply node 52 and a source 62 electrically connected to the dormant supply node 54. The switching unit 48 is configured to selectively couple the first device power terminal 34 (i.e., the active supply node 52) and the dormant local supply 26 (i.e., the dormant local supply node 54) in an on mode in response to a connection of the shield node 50 to the ground source 28 and decouple the first device power terminal 34 and the dormant local supply 26 in an off mode in response to a lack of connection between the shield node 50 and the ground source 28. It should be appreciated that other types of electrical or mechanical switches may be employed instead of the MOSFET 56, such as, but not limited to a bipolar junction transistor (BJT) or relay. The MOSFET 56 includes an over voltage diode 64 electrically connected between the drain 60 and the source 62 for suppressing over voltage transients and electrical noise through the MOSFET 56. The switching unit 48 also includes a zener diode 66 electrically connected between the shield node 50 and the dormant supply node 54 and a resistor 68 electrically connected in parallel with the zener diode 66. The zener diode 66 prevents excessive voltage between the gate 58 of the MOSFET 56 and the source 62 of the MOSFET 56.

A cable subassembly 70 has a first end and a second end and a plurality of cable conductors (not shown) extending from the first end to the second end for electrically interconnecting the first device 22 and a second device (e.g. a personal computer). The cable subassembly 70 includes a shield (not shown) annularly disposed about the cable conductors and extending from the first end to the second end of the cable subassembly 70 for shielding the cable conductors from electromagnetic interference and for preventing the cable conductors from emitting electromagnetic interference.

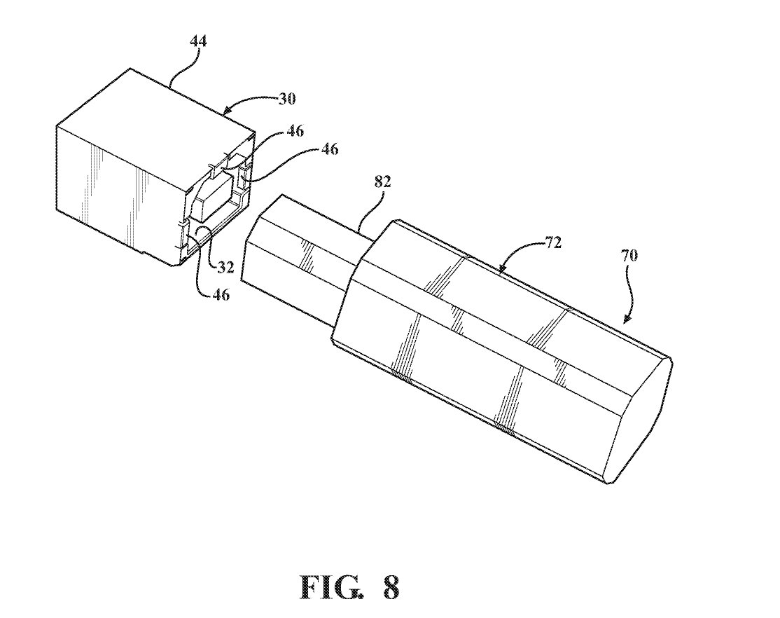

The cable subassembly 70 includes a first cable connector 72 disposed at the first end of the cable assembly and includes a plurality of first cable connector terminals 74, 76, 78, 80 (FIG. 5) electrically connected to the cable conductors for connection to the first device connector 30. The first cable connector terminals 74, 76, 78, 80 include a first cable power terminal 74 and a first cable ground terminal 76 and a first cable positive data terminal 78 and a first cable negative data terminal 80. The first cable connector terminals 74, 76, 78, 80 are each configured for electrically connecting to corresponding first device terminals 34, 36, 38, 40 (i.e. the first cable power terminal 74 can engage the first device power terminal 34, the first cable ground terminal 76 can engage the first device ground terminal 36, first cable positive data terminal 78 can engage first device positive data terminal 38, and first cable negative data terminal 80 can engage first device negative data terminal 40). The first cable connector 72 also includes a first shell 82 (FIG. 8) extending longitudinally from the cable subassembly 70 and disposed about and in a spaced relationship from the first cable connector terminals 74, 76, 78, 80 and electrically connected to the shield of the cable subassembly 70 for inserting into the cavity 32 and engaging the tabs 46 of the housing 44 of the first device connector 30 to form an electrical connection between the housing 44 and the shield of the cable subassembly 70, as shown in FIG. 5.

According to an aspect, the cable subassembly 70 additionally may include a second cable connector (not shown) disposed at the second end of the cable assembly and including a plurality of second cable connector terminals (not shown) electrically connected to the cable conductors. The second cable connector may include a second shell (not shown) extending longitudinally from the cable subassembly 70 and disposed about and in a spaced relationship from the second cable connector terminals and electrically connected to the shield of the cable subassembly 70. The second cable connector terminals can include a second cable power terminal and a second cable ground terminal and a second cable positive data terminal and a second cable negative data terminal. It should be understood that while the switching system 20 may include a second cable connector as described above, the switching system 20 may not include a second cable conductor and may be directly attached to or “hard-wired” to the second device, for example.

The shield of the cable subassembly 70 is electrically connected to the first cable ground terminal (as shown by a dashed line in FIG. 1) for electrically interconnecting the shield of the cable subassembly 70 and the ground source 28 in response to the first cable connector 72 of the cable subassembly 70 engaging the first device connector 30. Specifically, in response to the first shell 82 of the first cable connector 72 engaging the tabs 46 of the housing 44. Consequently, a conductive path is formed from the shield node 50 to the ground source 28 through the shield which activates the switching unit 48 to electrically couple the first device power terminal 34 to the dormant local supply 26 (through the dormant supply node 54) and provide voltage from the first device power terminal 34 to the dormant local supply 26. When the first shell 82 of the first cable connector 72 disengages the tabs 46, no conductive path exists from the shield node 50 to the ground source 28 through the shield. Consequently, the switching unit 48 is deactivated (i.e. in the off mode) and the first device power terminal 34 and the dormant local supply 26 are no longer electrically coupled. According to an aspect, the second device may be a personal computer which is configured to supply voltage (e.g. 5V) through the cable subassembly 70 to the first device power terminal 34, which can then provide voltage from the first device power terminal 34 (e.g. active USB supply voltage) through the active supply node 52 to the dormant local supply 26 at the dormant supply node 54. Although the first device ground terminal 36 and the shield may be electrically connected when the first cable connector 72 is connected to the first device connector 30 according to one aspect of the disclosure (e.g., for low-side switching of the MOSFET 56), it should be appreciated that the shield could for example be electrically connected to the first device power terminal 34 and the source 62 and the drain 60 of the MOSFET 56 could be reversed. As a result, the switching unit 48 would transition to the on mode due to a positive voltage from the gate 58 of the MOSFET 56 to the source 62 of the MOSFET 56 (i.e. the MOSFET 56 can be configured to operate using either high-side switching or low-side switching).

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. Those skilled in the art will recognize that concepts disclosed in association with an example switching system 20 can likewise be implemented into many other systems to control one or more operations and/or functions.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

Obviously, many modifications and variations of the present invention are possible in light of the above teachings and may be practiced otherwise than as specifically described while within the scope of the appended claims.

What is claimed is:

1. A device comprising:
an active supply node for coupling to an active electrical supply from a second device;
a dormant local supply node for selectively supplying power to said device;
a first device connector for coupling with the second device through a cable subassembly; and
a switching unit coupled to said dormant local supply node and said active supply node and to said first device connector, said switching unit configured to selectively decouple said active supply node and said dormant local supply node in an off mode in response to the cable subassembly disengaging said first device connector and to couple said active supply node to said dormant local supply node in an on mode in response to the cable subassembly engaging said first device connector.

2. A device as set forth in claim 1, wherein said switching unit includes a MOSFET.

3. A device as set forth in claim 1, wherein said MOSFET is configured to operate using low-side switching.

4. A device as set forth in claim 1, wherein said first device connector is a USB type connector and said second device comprises a personal computer configured to supply voltage through said cable subassembly into said first device connector and to said dormant local supply node.

5. A device comprising:
an active supply node for coupling to an active electrical supply from a second device;
a dormant local supply node for selectively supplying power to said device;
a first device connector having a plurality of first device terminals for coupling with the second device through a cable subassembly, wherein the cable subassembly includes a first cable connector including a plurality of first cable connector terminals for connection to said first device terminals and a shield electrically connected to the first cable connector and at least one of the first cable connector terminals;
a shield node for coupling with the shield of the cable subassembly through said first device connector; and
a switching unit coupled to said dormant local supply node and said active supply node and to said shield node, said switching unit operable for selectively decoupling said active supply node and said dormant local supply node in an off mode in response to the first cable connector of the cable subassembly disengaging said first device connector and for coupling said active supply node to said dormant local supply node in an on mode in response to the first cable connector of the cable subassembly engaging said first device connector and forming a conductive path through the shield and said at least one of said first device terminals to activate said switching unit.

6. A device as set forth in claim 5, wherein said switching unit includes a MOSFET having a gate electrically connected to said shield node, a drain electrically connected to said active supply node, and a source electrically connected to said dormant supply node.

7. A device as set forth in claim 6, wherein said switching unit includes a zener diode electrically connected between said shield node and said dormant supply node for preventing excessive voltage between said gate of said MOSFET and said source of said MOSFET and a resistor connected in parallel with said zener diode.

8. A device as set forth in claim 5, wherein said first device connector includes a housing disposed about and in a spaced relationship with said first device terminals to define a cavity and said first device terminals include a first device power terminal electrically connected with said active supply node and a first device ground terminal electrically interconnected with a ground source and a first device positive data terminal and a first device negative data terminal and a plurality of tabs are coupled to said housing and extend into said cavity for engaging the first cable connector of the cable subassembly.

9. A device a set forth in claim 8, further including a capacitor electrically connected between said first device power terminal and said ground source for filtering electrical noise.

10. A device a set forth in claim 5, wherein said first device connector comprises a USB type connector and said second device comprises a personal computer configured to supply voltage through the cable subassembly into said first device connector and to said dormant local supply node.

11. A switching system comprising:
a first device including a dormant local supply for selectively powering said first device and a first device connector having a plurality of first device terminals, said first device including a switching unit for selectively coupling at least one of said plurality of first device terminals to said dormant local supply in an on mode and for decoupling at least one of said first device terminals and said dormant local supply in an off mode;
a cable subassembly including a shield and a first cable connector having a plurality of first cable connector terminals for connection to said first device terminals; and
a second device coupled to said cable subassembly for selectively providing power to said first device through at least one of said plurality of first device terminals;
said shield of said cable subassembly being electrically connected to at least one of said first cable connector terminals for electrically interconnecting at least one of said first device terminals to said dormant local supply in response to said first cable connector of said cable subassembly engaging said first device connector and forming a conductive path through said shield and at least one of said first device terminals and activating said switching unit.

12. A switching system as set forth in claim 11, wherein said cable subassembly has a first end and a second end and includes a plurality of cable conductors extending from said first end to said second end and connected to said first cable connector terminals for interconnecting said first device to a second device and said shield is annularly disposed about said plurality of cable conductors.

13. A switching system as set forth in claim 12, wherein said first device includes a ground source and said first cable connector terminals of said cable subassembly include a first cable ground terminal and said shield of said cable subassembly is connected to said first cable ground terminal and said first device terminals include a first device ground terminal electrically connected to said ground source.

14. A switching system as set forth in claim 13, wherein said switching unit includes a shield node for coupling to said shield and an active supply node for coupling to an active electrical supply from a second device and a dormant local supply node for selectively supplying power to said first device and said switching unit includes a MOSFET having a gate electrically connected to said shield node and a drain electrically connected to said active supply node and a source electrically connected to said dormant supply node.

15. A switching system as set forth in claim 14, wherein said first device connector includes a housing disposed about and in a spaced relationship with said first device terminals to define a cavity and electrically connected to said shield node and wherein said first device terminals include a first device power terminal electrically connected with said active supply node and a first device ground electrically interconnected with a ground source and a first device positive data terminal and a first device negative data terminal.

16. A switching system as set forth in claim 15, wherein said first device further includes a capacitor electrically connected between said first device power terminal and said ground source for filtering electrical noise.

17. A switching system as set forth in claim 15, wherein said housing includes a plurality of tabs extending into said cavity for engaging the first cable connector of the cable subassembly.

18. A switching system as set forth in claim 17, wherein said first cable connector includes a first shell extending longitudinally from the cable subassembly and disposed about and in a spaced relationship with said first cable connector terminals and electrically connected to said shield for inserting in said cavity and engaging said tabs of said housing of said first device connector to form an electrical connection between said housing and said shield of said cable subassembly.

19. A switching system as set forth in claim 18, wherein said switching unit includes a zener diode electrically connected between said shield node and said dormant supply node for preventing excessive voltage between said gate of said MOSFET and said source of said MOSFET and a resistor connected in parallel with said zener diode.

20. A switching system as set forth in claim 11, wherein said first device connector is a USB type connector and said second device comprises a personal computer configured to supply voltage through said cable subassembly into said first device connector and to said dormant local supply.
